(19) United States
(12) Patent Application Publication
(10) Pub. No.: US 2006/0213645 A1
(43) Pub. Date: Sep. 28, 2006

(54) Integral liquid cooling unit for a computer

(76) Inventors: Douglas C. Wintersteen, Burt, NY (US); Don C. Corser, Lockport, NY (US)

Correspondence Address: DELPHI TECHNOLOGIES, INC., M/C 480-410-202, PO BOX 5052, TROY, MI, 48007, US

(21) Appl. No.: 11/088,414

(22) Filed: Mar. 24, 2005

(51) Int. Cl. H05K 7/20

(52) U.S. Cl. 165/104.19; 361/699

(57) ABSTRACT

An integral liquid cooling unit for an electronic device comprises a manifold defining a plurality of heat sink compartments for heat exchange engagement with the electronic device. The manifold presents a platform for sealing engagement with a pump. The manifold also presents an inlet and an outlet and defines internal passages establishing fluid communication between the pump and the inlet and outlet through the heat sink compartments. A heat exchanger is mounted directly to the manifold and in fluid communication with the inlet and outlet of the manifold. More specifically, the heat exchanger includes a first tank and a second tank each defined by a cylindrical tube with an open lower end of the first tank extending into and in sealed engagement with the inlet in the manifold and an open lower end of the second tank extending into and in sealed engagement with the outlet in the manifold.

### BACKGROUND OF THE INVENTION

1. Field of the Invention

An integral liquid cooling unit for an electronic device.

2. Description of the Prior Art

Many electronic systems produce heat that is detrimental to the electronic system and must be dissipated. Accordingly, a wide variety of heat sinks have been developed for extracting and dissipating such heat. As illustrated in U.S. Pat. Nos. 3,361,195 to Meyerhoff et al and 6,257,320 to Wargo, such systems may include a manifold defining a heat sink compartment presenting an outer surface for heat exchange engagement with an electronic device. Still further, the manifold may present a pump-platform for sealing engagement with a pump with the manifold presenting an inlet and an outlet in fluid communication with the pump through internal passages in the manifold, as illustrated in U. S. Patent Application Publication No. 2002/0039280 A1 of Apr. 4, 2002 in the name of O'Conner et al.

A major concern in developing such cooling systems is to avoid the potential for leakage of the cooling fluid. The use of hoses or flexible conduits to interconnect the components increases the potential for leakage at the connections. In addition, such flexible hoses or conduits are susceptible to wear and leakage from rupture under pressure. The potential for leakage is increased because of the difficulty of assembly or connections of such hoses and conduits, let alone the labor and time costs of such assembly. It is also frequently difficult to match compatible materials in the hoses and conduits with the coolant fluid and/or environmental extremes to which such systems are subjected.

### SUMMARY OF THE INVENTION AND ADVANTAGES

The subject invention provides an integral liquid cooling unit for an electronic device wherein a heat exchanger is mounted to a manifold so as to be in fluid communication with the inlet and outlet and internal passages of the manifold.

Accordingly, the subject invention decreases the risk of leakage and the resultant coolant loss.

### BRIEF DESCRIPTION OF THE DRAWINGS

Other advantages of the present invention will be readily appreciated, as the same becomes better understood by reference to the following detailed description when considered in connection with the accompanying drawings wherein:

FIG. 1 is a perspective view of an embodiment of the manifold of the subject invention made of top and bottom plates;

FIG. 2 is a fragmentary cross sectional view of a manifold of the subject invention;

FIG. 3 is another view like FIG. 2 but showing a variation of the manifold construction; and

FIG. 4 is a plan view of an embodiment of the manifold of the subject invention made of one solid block.

### DETAILED DESCRIPTION OF THE PREFERRED EMBODIMENT

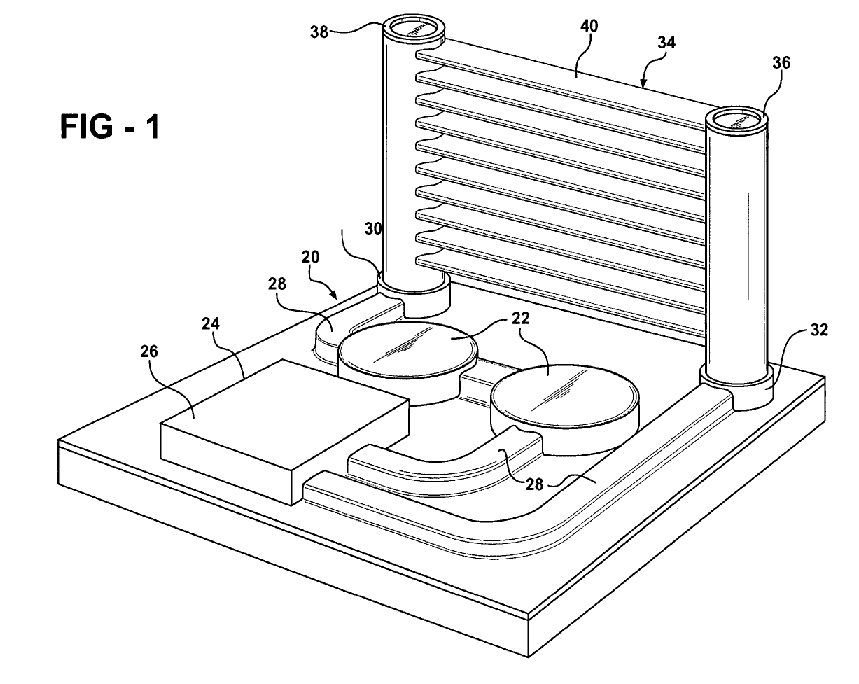

An integral liquid cooling unit for an electronic device constructed in accordance with the subject invention is shown in FIGS. 1 and 4.

The unit is fabricated about a manifold, generally indicated at 20, defining a plurality of heat sink compartments 22 each presenting an outer surface for heat exchange engagement with an electronic device (not shown).

The manifold 20 presents a platform 24 for sealing engagement with a pump 26. The pump 26 is secured to and supported by the manifold 20 in sealing engagement with the platform 24. The pump 26 may be secured by fasteners, or the like, with seals, gaskets, O-rings, or the like, sealing the pump 26 to the platform 24. The pump 26 includes ports in direct sealed engagement with openings into the internal passages 28 in the manifold 20.

The manifold 20 also presents an inlet 30 and an outlet 32 and defines internal passages 28 establishing fluid communication between the pump 26 and the inlet 30 and outlet 32 through the heat sink compartments 22.

A heat exchanger, generally indicated at 34, is mounted to the manifold 20 and in fluid communication with the inlet 30 and outlet 32 of the manifold 20. More specifically, the heat exchanger 34 includes a first tank 36 and a second tank 38 spaced from the first tank 36 with a core 40 extending between the tanks 36, 38 for conducting fluid flow between the tanks 36, 38 while extracting heat, the core 40 being of the well known type including tubular elements for conducting fluid between the tanks 36, 38 with fins between the fluid conveying elements to exchange heat with air flowing through the fluid conveying elements. Each tank 36, 38 is defined by a cylindrical tube with an open lower end of the first tank 36 extending into the inlet 30 in the manifold 20 and an open lower end of the second tank 38 extending into the outlet 32 in the manifold 20. The top end of each of the tanks 36, 38 is capped or other wise sealed whereby fluid enters the first tank 36 from the pump 26 through the internal passages 28 and passes through the core 40 to the second tank 38 and back into the internal passages 28 and to the heat sink compartments 22. The first tank 36 is supported in sealed engagement with the inlet 30 and the second tank 38 is supported in sealed engagement with the outlet 32. This may accomplished by the manifold 20 and tanks 36, 38 being metal with the tanks 36, 38 brazed (welded) in the inlet 30 and outlet 32. Alternatively, the tanks 36, 38 may be attached to the manifold 20 by fasteners with O-rings, gaskets, seals, or the like, sealing the tanks 36, 38 to the inlet 30 and outlet 32. The manifold 20 is disposed in a plane containing the horizontal X and Y axes and thereby extends along at least one horizontal axis and the tanks 36, 38 extend along a vertical Z axis that is transverse to the axis (X or Y) of the manifold 20. The manifold 20 a bottom surface and a top surface extending laterally of the horizontal axis X or Y.

The outer surface of the heat sink compartment 22 is disposed in one of the top and bottom surfaces of the manifold 20 whereas the platform 24 for the pump 26 is disposed on the top surface. The internal passages 28 extend through the interior of the manifold 20 and are spaced from and between the top and bottom surfaces thereof.

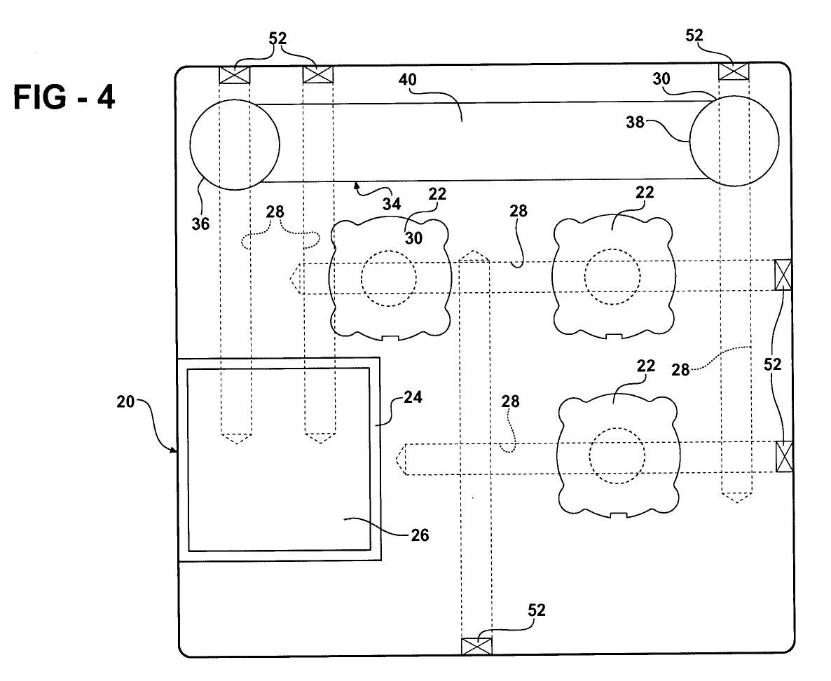

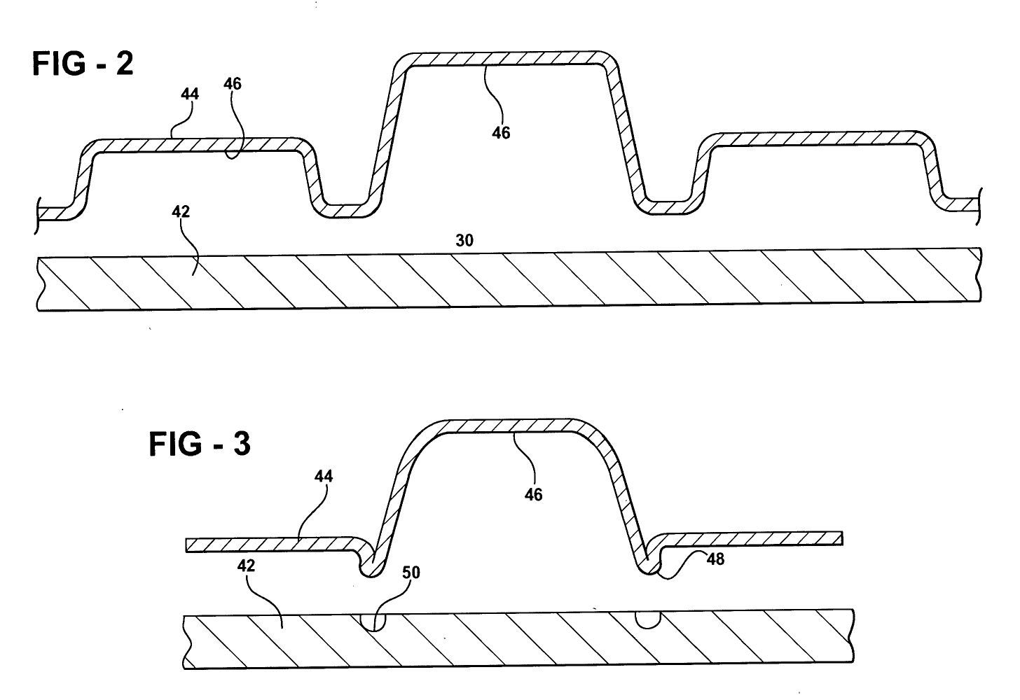

As illustrated in FIGS. 1, 2 and 3, the manifold 20 comprises a bottom plate 42 and a top plate 44 in sealed engagement with the bottom plate 42. The bottom plate 42 is rigid and the top plate 44 of the 2-piece manifold may or may not be of less thickness than the bottom plate 42, i.e., the top plate 44 may be a stamping made in a press to present grooves 46 defining the internal passages 28. As shown in FIG. 2, the bottom plate 42 presents a smooth or flat upper surface and the top plate 44 presents the grooves 46 open to and sealed by the upper surface of the bottom plate 42. The top plate 44 may be sealed to the bottom plate 42 by gaskets or the metals thereof may be brazed together. In addition, as illustrated in FIG. 3, the top plate 44 may include ribs 48 along the internal passages 28 for engaging a complimentary rut 50 in the bottom plate 42. on the other hand, the manifold 20 may be a solid block of homogenous material, as illustrated in FIG. 4. when a solid block of material, the passages 28 are drilled on different levels between the top and bottom surfaces and are plugged by plugs 52.

Obviously, many modifications and variations of the present invention are possible in light of the above teachings. The invention may be practiced otherwise than as specifically described within the scope of the appended claims.

What is claimed is:

1. An integral liquid cooling unit for an electronic device comprising;
a manifold defining at least one heat sink compartment presenting an outer surface for heat exchange engagement with an electronic device,
said manifold presenting a platform for sealing engagement with a pump,
said manifold presenting an inlet and an outlet,
said manifold defining internal passages establishing fluid communication between said pump and said inlet and outlet through said heat sink compartment, and
a heat exchanger mounted to said manifold and in fluid communication with said inlet and outlet of said manifold.

2. An integral liquid cooling unit as set forth in claim 1 wherein said heat exchanger includes a first tank and a second tank spaced from said first tank with a core extending between said tanks for conducting fluid flow between said tanks while extracting heat.

3. An integral liquid cooling unit as set forth in claim 2 wherein said first tank is supported in sealed engagement with said inlet and said second tank is supported in sealed engagement with said outlet.

4. An integral liquid cooling unit as set forth in claim 3 wherein each of said tanks is defined by a tube with the end of said first tank extending into said inlet and said second tank extending into said outlet.

5. An integral liquid cooling unit as set forth in claim 3 wherein said manifold extends along an axis and said tanks extend transversely to said axis of said manifold.

6. An integral liquid cooling unit as set forth in claim 3 wherein said mounting plate and said tanks comprise metal and said tanks are welded to said manifold.

7. An integral liquid cooling unit as set forth in claim 3 wherein said manifold extends along an axis and presents a bottom surface and a top surface extending laterally of said axis.

8. An integral liquid cooling unit as set forth in claim 7 wherein said outer surface of said heat sink compartment is disposed in one of said top and bottom surfaces.

9. An integral liquid cooling unit as set forth in claim 8 wherein said platform is disposed on said top surface.

10. An integral liquid cooling unit as set forth in claim 9 wherein said internal passages extend through said manifold and spaced from and between said top and bottom surfaces thereof.

11. An integral liquid cooling unit as set forth in claim 10 wherein said manifold is a solid homogenous material.

12. An integral liquid cooling unit as set forth in claim 10 wherein said manifold comprises a bottom plate and a top plate in sealed engagement with said bottom plate.

13. An integral liquid cooling unit as set forth in claim 12 wherein said bottom plate is rigid and said top plate of the 2-piece manifold may or may not be of less thickness than the bottom plate.

14. An integral liquid cooling unit as set forth in claim 13 wherein said top plate defines said internal passages.

15. An integral liquid cooling unit as set forth in claim 14 wherein said bottom plate presents a smooth upper surface and said top plate presents grooves open to and sealed by said upper surface of said bottom plate.

16. An integral liquid cooling unit as set forth in claim 3 including a pump secured to and supported by said manifold in sealing engagement with said pump platform.

17. An integral liquid cooling unit as set forth in claim 16 wherein said pump includes an inlet port and an outlet port in direct sealed engagement with openings into said internal passages in said manifold.
